(19) United States
(12) Patent Application Publication
(10) Pub. No.: US 2021/0182523 A1
(43) Pub. Date: Jun. 17, 2021

(54) FINGERPRINT IDENTIFICATION STRUCTURE OF DISPLAY

(71) Applicant: WUHAN CHINA STAR OPTOELECTRONICS SEMICONDUCTOR DISPLALYTECHNOLOGY CO.,LTD., Wuhan,Hubei (CN)

(72) Inventor: Yalong MA, (US)

(73) Assignee: WUHAN CHINA STAR OPTOELECTRONICS SEMICONDUCTOR DISPLAYTECHNOLOGY CO., LTD., Wuhan, Hubei (CN)

(21) Appl. No.: 16/468,016

(22) PCT Filed: Mar. 11, 2019
(86) PCT No.: PCT/CN2019/077677

§ 371 Date: Jun. 10, 2019

(30) Foreign Application Priority Data
Dec. 20, 2018 (CN) 201811562168.6

(51) Int. Cl. G06K 9/00; G06K 9/20; H01L 51/00; H01L 51/52

(52) U.S. Cl. CPC G06K 9/0004; G06K 9/2036; G06K 9/00046; H01L 27/3244; H01L 51/5275; H01L 51/5234; H01L 51/0096

(57) ABSTRACT

A fingerprint identification structure of a display screen includes: a fingerprint module; a substrate layer disposed on the fingerprint module, a hollow space defined between the substrate layer and the fingerprint module, and a plurality of anti-total reflection structures arranged on a side of the substrate layer facing the fingerprint module; an organic light- emitting layer disposed on the substrate layer; and a surface layer disposed above the organic light- emitting layer. When each light beam passing through a conical structure is incident on a surface of the conical structure, if total reflection occurs, only partial reflection occurs on the other side, which is equivalent to changing part of the total reflected light to the partially reflected light, that is, the percentage of transmitted light is increased, so that the brightness of the light received by the fingerprint module is also increased, thereby increasing the sensitivity of the fingerprint module.

### BACKGROUND OF INVENTION

### Field of Invention

The present invention relates to a technical field of fingerprint identification structures, in particular to a sensitive in-screen display fingerprint recognition structure of an active matrix organic light emitting diode (AMOLED).

### Description of Prior Art

At present, mobile phones with an in-screen optical fingerprint recognition function have appeared on the market, wherein light emitted by the active matrix organic light emitting diodes (AMOLEDs) is reflected by a fingerprint on a surface layer to reach a back of a screen, and then received by a fingerprint module to form a fingerprint image, thereby performing fingerprint recognition actions. The existing fingerprint identification structure also has another reflection at a bottom of a substrate of the AMOLED, wherein partial reflection occurs when an incident angle is small, while total reflection occurs when the incident angle reaches a total reflection condition, wherein the total reflection has the biggest impact, which will greatly reduce brightness of the fingerprint that the fingerprint module can receive, thus negatively affecting sensitivity of fingerprint recognition.

The existing fingerprint identification structure also has another reflection at a bottom of a substrate of an active matrix organic light emitting diode (AMOLED), wherein partial reflection occurs when the incident angle is small, while total reflection occurs when the incident angle reaches the total reflection condition, wherein the total reflection has the largest impact, which will greatly reduce the brightness of the fingerprint that the fingerprint module can receive, thus negatively affecting fingerprint recognition sensitivity.

### SUMMARY OF INVENTION

An object of the present invention is to provide a fingerprint identification structure of a display screen, including: a fingerprint module; a substrate layer disposed on the fingerprint module, a hollow space being defined between the substrate layer and the fingerprint module, a plurality of anti-total reflection structures being arranged on a side of the substrate layer facing the fingerprint module; an organic light-emitting layer disposed on the substrate layer; and a surface layer disposed above the organic light-emitting layer. Accordingly, when each light beam passing through a conical structure is incident on a surface of the conical structure, if total reflection occurs, only partial reflection occurs on the other side, which is equivalent to changing part of the total reflected light to the partially reflected light, that is, the percentage of transmitted light is increased, so that the brightness of the light received by the fingerprint module is also increased, thereby increasing the sensitivity of the fingerprint module.

In some embodiments, the anti-total reflection structures are conical protruding structures.

In some embodiments, a transparent cathode layer is disposed on the organic light-emitting layer.

In some embodiments, a protective layer is disposed on the transparent cathode layer.

In some embodiments, a plurality of intermediate layers are disposed between the protective layer and the surface layer.

In some embodiments, an intermediate layer is disposed between the protective layer and the surface layer.

In some embodiments, the hollow space is defined by a sealant between the substrate layer and the fingerprint module.

In some embodiments, plurality of anti-total reflection structures are a plurality of conical protruding structures arranged in a matrix.

In some embodiments, each of the conical protruding structures has a conical angle α ranging from

$$\frac{π}{2} - arcsin \frac{n 1}{n 2} < α < 2 arcsin \frac{n 1}{n 2} ,$$

where n2 is a refractive index of the substrate layer, and n1 is a refractive index of a medium in the hollow space.

An object of the present invention is to provide a display device including the fingerprint recognition structure as described above, and the fingerprint recognition structure is an optical fingerprint recognition structure.

The beneficial effects of the present invention are that when each light beam passing through a conical structure is incident on a surface of the conical structure, if total reflection occurs, only partial reflection occurs on the other side, which is equivalent to changing part of the total reflected light to the partially reflected light, that is, the percentage of transmitted light is increased, so that the brightness of the light received by the fingerprint module is also increased, thereby increasing the sensitivity of the fingerprint module.

### BRIEF DESCRIPTION OF DRAWINGS

FIG. 1 is a cross-sectional view showing a fingerprint identification structure of a display screen according to an embodiment of the present invention.

FIG. 2 is a partial cross-sectional view of a fingerprint identification structure of a display screen according to another embodiment of the present invention.

FIG. 3 is a schematic top view showing a conical protruding structure arranged in a matrix in a fingerprint identification structure of a display screen according to an embodiment of the present invention.

FIG. 4A is a schematic diagram of an internal light path of a conical protruding structure of a fingerprint identification structure of a display screen according to an embodiment of the present invention.

FIG. 4B is a schematic diagram of an internal light path of a conical protruding structure of a fingerprint identification structure of a display screen according to another embodiment of the present invention.

### DETAILED DESCRIPTION OF PREFERRED EMBODIMENTS

The following description of the various embodiments is provided to illustrate the specific embodiments of the invention. The spatially relative directional terms mentioned in the present invention, such as “upper”, “lower”, “before”, “after”, “left”, “right”, “inside”, “outside”, “side”, etc. and the like, may be used herein for ease of description to describe one element or feature's relationship to another element(s) or feature(s) as illustrated in the figures which are merely references. The spatially relative terms are intended to encompass different orientations in addition to the orientation as depicted in the figures.

In the present specification, like numbers refer to like elements throughout the description of the figures.

Reference throughout this specification to “one embodiment” or “an embodiment” means that a particular feature, structure, or characteristic described in conjunction with the embodiment is included in at least one embodiment of the present disclosure. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

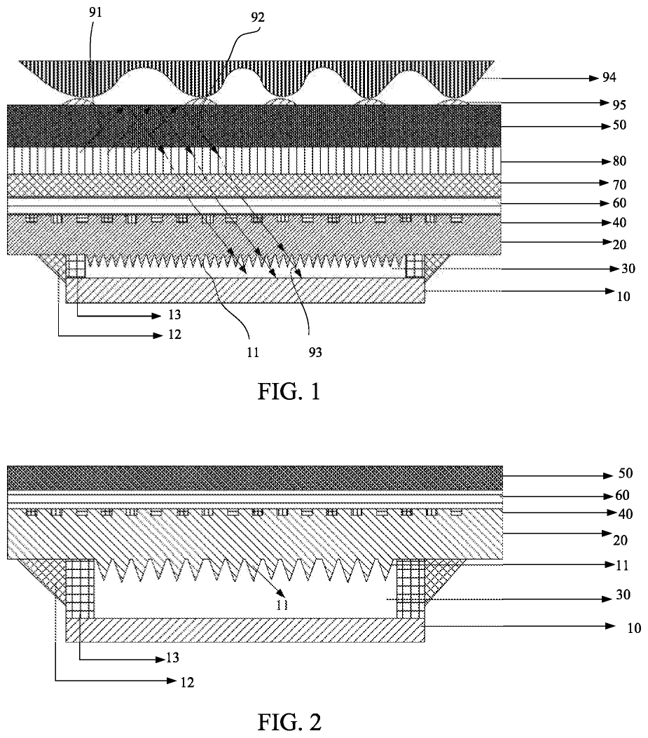

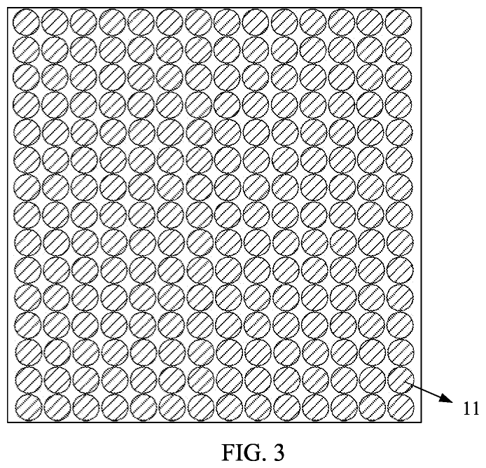

Referring to FIG. 1 to FIG. 4B, in view of a light path, light 91 emitted by an active matrix organic light emitting diode (AMOLED) becomes a reflected light 92 by a fingerprint 94, or sweat 95 on a surface layer 50 to reach the back of a screen and becomes transmitted light 93, and is then received by a fingerprint module 10 to form a fingerprint image, thereby performing a fingerprint recognition operation. An object of the present invention is to provide a fingerprint identification structure of a display screen, including: a fingerprint module 10; a substrate layer 20 disposed on the fingerprint module 10, a hollow space 30 defined between the substrate layer 20 and the fingerprint module 10, a plurality of anti-total reflection structures 11 arranged on a side of the substrate layer 20 facing the fingerprint module 10; an organic light emitting layer 40 disposed on the substrate layer 20; and a surface layer 50 disposed above the organic light emitting layer 40. Accordingly, when each light beam passing through a conical structure is incident on a surface of the conical structure, if total reflection occurs, only partial reflection occurs on the other side, which is equivalent to changing part of the total reflected light to the partially reflected light, that is, the percentage of transmitted light is increased, so that brightness of the light received by the fingerprint module 10 is also increased, thereby increasing sensitivity of the fingerprint module 10. Another object of the present invention is to reduce the occurrence of total reflection on a bottom surface of the AMOLED substrate layer and to increase the transmitted light.

In some embodiments, wherein the anti-total reflection structures 11 are conical protruding structures.

In some embodiments, a transparent cathode layer 60 is disposed on the organic light emitting layer 40.

In some embodiments, a protective layer 70 is disposed on the transparent cathode layer 60.

In some embodiments, a plurality of intermediate layers 80 are disposed between the protective layer 70 and the surface layer 50.

In some embodiments, an intermediate layer 80 is disposed between the protective layer 70 and the surface layer 50.

In some embodiments, the hollow space 30 is defined by a sealant 12 and a frame glue 13 between the substrate layer 20 and the fingerprint module 10.

In some embodiments, the plurality of anti-total reflection structures 11 are a plurality of conical protruding structures arranged in a matrix.

In some embodiments, each of the conical protruding structures 11 has a conical angle α, which has a range calculated with respect to the following rule: n2 is known as a refractive index of an AMOLED substrate, and n1 is refractivity of a medium in a hollow space (gap), and therefore, when the light in the AMOLED substrate is incident on an interface between the substrate and the medium in the hollow space (gap), a critical angle at which total reflection occurs is

$$β2 - arcsin \frac{n 1}{n 2} < α < β1 + arcsin \frac{n 1}{n 2} .$$

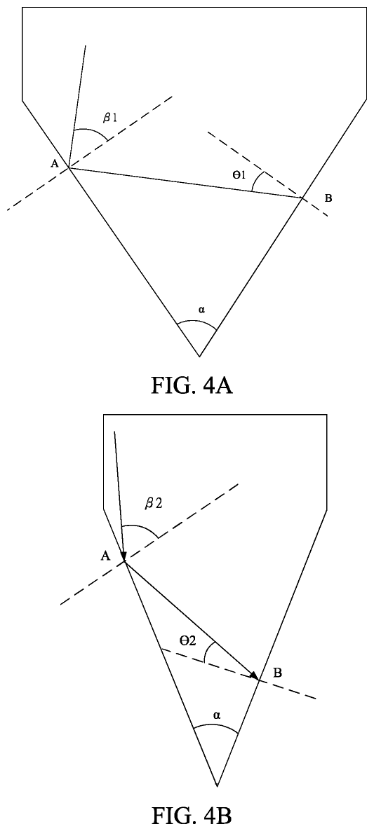

As shown in FIG. 4A (maximum value of α) and FIG. 4B (minimum value of α), two types of light paths of total reflection are shown (the arrow is the light path, and the dotted line is a perpendicular line of the interface), and the light is totally reflected at location A to reach location B. It can be obtained from FIGS. 4A and 4B.

To make total reflection not to occur at location B, it should will comply with the following formula:

$$θ1 = α - β1 < arcsin \frac{n 1}{n 2}$$

$$θ2 = β2 - α < arcsin \frac{n 1}{n 2} \\ \to β2 - arcsin \frac{n 1}{n 2} < α < β1 + arcsin \frac{n 1}{n 2}$$

Under a premise that total reflection occurs at location A, the minimum value is

$$arcsin \frac{n 1}{n 2} ,$$

and the minimum value of

$$β1 + arcsin \frac{n 1}{n 2} 2$$

is:

$$2 arcsin \frac{n 1}{n 2} 2.$$

The maximum value of β2 is π/2, and the maximum value of

$$β2 - arcsin \frac{n 1}{n 2}$$

is:

$$\frac{π}{2} - arcsin \frac{n 1}{n 2} .$$

In summary, the following formula is obtained.

$$\frac{π}{2} - arcsin \frac{n 1}{n 2} < α < 2 arcsin \frac{n 1}{n 2}$$

Each of the conical protruding structures has a conical angle α ranging from

$$\frac{π}{2} - arcsin \frac{n 1}{n 2} < α < 2 arcsin \frac{n 1}{n 2} ,$$

where n2 is a refractive index of the substrate layer 20, and n1 is a refractive index of a medium in the hollow space 30. Accordingly, when each light beam passing through a conical structure is incident on a surface of the conical structure, if total reflection occurs, only partial reflection occurs on the other side, which is equivalent to changing part of the total reflected light to the partially reflected light, that is, the percentage of transmitted light is increased, so that the brightness of the light received by the fingerprint module 10 is also increased, thereby increasing the sensitivity of the fingerprint module 10. Another object of the present invention is to reduce the occurrence of total reflection on the bottom surface of the AMOLED substrate layer and to increase the transmitted light.

In addition, another object of the present invention is to provide a display device including the fingerprint identification structure as described above, and the fingerprint recognition structure is an optical fingerprint recognition structure.

While the invention has been described by way of example and in terms of the preferred embodiments, it is to be understood that the invention is not limited to the disclosed embodiments. To the contrary, it is intended to cover various modifications and similar arrangements. Therefore, the scope of the appended claims should be accorded the broadest interpretation so as to encompass all such modifications and similar arrangements.

What is claimed is:

1. A fingerprint identification structure of a display screen, comprising:
a fingerprint module;
a substrate layer disposed on the fingerprint module, a hollow space defined between the substrate layer and the fingerprint module, and a plurality of anti-total reflection structures arranged on a side of the substrate layer facing the fingerprint module;
an organic light emitting layer disposed on the substrate layer; and
a surface layer disposed above the organic light emitting layer.

2. The fingerprint recognition structure of the display screen according to claim 1, wherein the anti-total reflection structures are conical protruding structures.

3. The fingerprint identification structure of the display screen according to claim 1, wherein a transparent cathode layer is disposed on the organic light emitting layer.

4. The fingerprint identification structure of the display screen according to claim 3, wherein a protective layer is disposed on the transparent cathode layer.

5. The fingerprint identification structure of the display screen according to claim 4, wherein a plurality of intermediate layers are disposed between the protective layer and the surface layer.

6. The fingerprint identification structure of the display screen according to claim 4, wherein an intermediate layer is disposed between the protective layer and the surface layer.

7. The fingerprint identification structure of the display screen according to claim 1, wherein the hollow space is defined by a sealant between the substrate layer and the fingerprint module.

8. The fingerprint recognition structure of the display screen according to claim 1, wherein the plurality of anti-total reflection structures are a plurality of conical protruding structures arranged in a matrix.

9. The fingerprint recognition structure of the display screen according to claim 8, wherein each of the conical protruding structures has a conical angle α ranging from
$$\frac{π}{2} - arcsin \frac{n 1}{n 2} < α < 2 arcsin \frac{n 1}{n 2} ,$$
wherein n2 is a refractive index of the substrate layer and n1 is a refractive index of a medium in the hollow space.

10. The fingerprint identification structure of the display screen according to claim 1, wherein the fingerprint identification structure is an optical fingerprint identification structure.

11. A display device, comprising: a fingerprint identification structure of a display screen, the fingerprint identification structure comprising:
a fingerprint module;
a substrate layer disposed on the fingerprint module, a hollow space defined between the substrate layer and the fingerprint module, a plurality of anti-total reflection structures arranged on a side of the substrate layer facing the fingerprint module;
an organic light emitting layer disposed on the substrate layer; and
a surface layer disposed above the organic light emitting layer.

12. The display device according to claim 11, wherein the anti-total reflection structures are conical protruding structures.

13. The display device according to claim 11, wherein a transparent cathode layer is disposed on the organic light emitting layer.

14. The display device according to claim 13, wherein a protective layer is disposed on the transparent cathode layer.

15. The display device according to claim 14, wherein a plurality of intermediate layers are disposed between the protective layer and the surface layer.

16. The display device according to claim 14, wherein an intermediate layer is disposed between the protective layer and the surface layer.

17. The display device according to claim 11, wherein the hollow space is defined by a sealant between the substrate layer and the fingerprint module.

18. The display device according to claim 11, wherein the plurality of anti-total reflection structures are a plurality of conical protruding structures arranged in a matrix.

19. The display device according to claim 11, wherein each of the conical projection structures has a conical angle α ranging from
$$\frac{π}{2} - arcsin \frac{n 1}{n 2} < α < 2 arcsin \frac{n 1}{n 2} ,$$
wherein n2 is a refractive index of the substrate layer, and n1 is a refractive index of a medium in the hollow space.

20. The display device according to claim 11, wherein the fingerprint identification structure is an optical fingerprint identification structure.
